(19) United States
(12) Patent Application Publication
(10) Pub. No.: US 2024/0162185 A1
(43) Pub. Date: May 16, 2024

(54) ELECTRONIC DEVICE

(71) Applicant: InnoLux Corporation, Miao-Li County (TW)

(72) Inventors: Chin-Ming HUANG, Miao-Li County (TW); Cheng-Chi WANG, Miao-Li County (TW); Kuan-Hsueh LIN, Miao-Li County (TW)

(73) Assignee: InnoLux Corporation, Miao-Li County (TW)

(21) Appl. No.: 18/088,609

(22) Filed: Dec. 25, 2022

(30) Foreign Application Priority Data
Nov. 16, 2022 (CN) 202211434036.1

(51) Int. Cl. H01L 23/00; H01L 23/31

(52) U.S. Cl. CPC H01L 24/81; H01L 23/3128; H01L 24/13; H01L 24/16; H01L 2224/13082; H01L 2224/13105; H01L 2224/13111; H01L 2224/13124; H01L 2224/13139; H01L 2224/13144; H01L 2224/13147; H01L 2224/13155; H01L 2224/16227; H01L 2224/81385

(57) ABSTRACT

An electronic device including a circuit structure, a bonding element and an electronic unit is disclosed. The circuit structure includes a conductive pad, and the conductive pad has an accommodating recess. At least a portion of the bonding element is disposed in the accommodating recess. The electronic unit is electrically connected to the conductive pad through the bonding element. The accommodating recess has a bottom surface and an opening opposite to the bottom surface, and a width of the bottom surface is greater than a width of the opening.

### BACKGROUND OF THE DISCLOSURE

### 1. Field of the Disclosure

The present disclosure relates to an electronic device, and more particularly to an electronic device including a conductive pad with an accommodating recess.

### 2. Description of the Prior Art

In recent years, because of the miniaturization and high density of electronic elements in electronic devices, various packaging technologies of electronic elements have been developed. However, in prior art, the displacement or production error may occur when aligning the elements in the electronic device for connecting the elements to each other, which leads to poor performance of the electrical property and reliability of the device after bonding process.

### SUMMARY OF THE DISCLOSURE

One of objectives of the present disclosure is to provide an electronic device, so as to solve the problems encountered by the conventional electronic devices, and the accuracy of alignment between elements may be improved through the structural design of the conductive pad, thereby improving the reliability of the electronic device.

An embodiment of the present disclosure provides an electronic device. The electronic device includes a circuit structure, a bonding element and an electronic unit. The circuit structure includes a conductive pad, and the conductive pad has an accommodating recess. At least a portion of the bonding element is disposed in the accommodating recess. The electronic unit is electrically connected to the conductive pad through the bonding element. The accommodating recess has a bottom surface and an opening opposite to the bottom surface, and a width of the bottom surface is greater than a width of the opening.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a cross-sectional schematic diagram of an electronic device according to an embodiment of the present disclosure.

FIG. 2 is a partially enlarged schematic diagram of a conductive pad and a bonding element shown in FIG. 1.

FIG. 3 is a cross-sectional schematic diagram of an electronic device according to another embodiment of the present disclosure.

FIG. 4 is a partial cross-sectional schematic diagram of a variation embodiment of a conductive pad and a bonding element according to the present disclosure.

FIG. 5 is a cross-sectional schematic diagram of an electronic device according to still another embodiment of the present disclosure.

FIG. 6 to FIG. 8 are schematic diagrams illustrating a part of the process of a conductive pad according to another embodiment of an electronic device of the present disclosure.

FIG. 9 is a partial cross-sectional schematic diagram illustrating the connection portion of a conductive pad shown in FIG. 8 and a bonding element.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in this document, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” mentioned in this document generally mean being within 20% of a given value or range, or being within 10%, 5%, 3%, 2%, 1% or 0.5% of a given value or range.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may include a semiconductor device, a package device, a display device, a light-emitting device, a backlight device, a solar cell, a sensing device, an antenna device, a vehicle device or a high-frequency device, but not limited herein. The electronic device may include a bendable or flexible electronic device. The display device may include a non-self-emissive display device or a self-emissive display device. The antenna device may include a liquid-crystal type antenna device or an antenna device other than liquid-crystal type, and the sensing device may include a sensing device used for sensing capacitance, light, heat or ultrasonic waves, but not limited herein. The electronic device may include electronic elements such as passive elements and active elements, for example, capacitors, resistors, inductors, diodes, transistors, etc. It should be noted that the electronic device may be any arrangement and combination of the above, but not limited herein.

It should be noted that the technical features in different embodiments described in the following can be replaced, recombined, or mixed with one another to constitute another embodiment without departing from the spirit of the present disclosure.

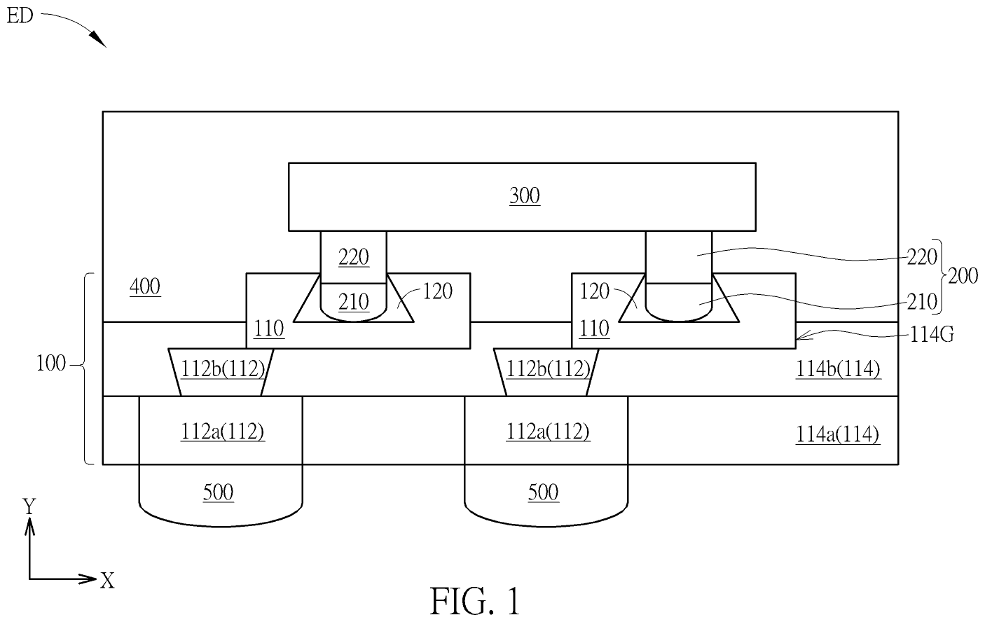

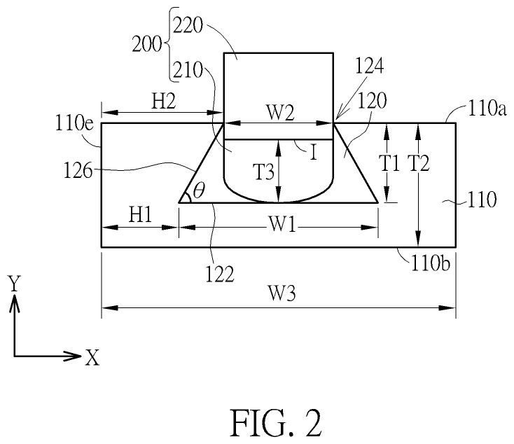

Please refer to FIG. 1 and FIG. 2. FIG. 1 is a cross-sectional schematic diagram of an electronic device according to an embodiment of the present disclosure. FIG. 2 is a partially enlarged schematic diagram of a conductive pad and a bonding element shown in FIG. 1. As shown in FIG. 1 and FIG. 2, an electronic device ED according to an embodiment of the present disclosure may include a circuit structure 100, a bonding element 200 and an electronic unit 300. The circuit structure 100 includes a conductive pad 110, and the conductive pad 110 has an accommodating recess 120. Specifically, the circuit structure 100 may include at least one conductive layer 112 (such as a conductive layer 112a and a conductive layer 112b), at least one insulating layer 114 (such as an insulating layer 114a and an insulating layer 114b) and one or plural conductive pads 110, which are stacked in a direction Y. The conductive pad 110 may be disposed on the uppermost insulating layer 114 and electrically connected to the uppermost conductive layer 112 in the circuit structure 100, for example, disposed on the insulating layer 114b and electrically connected to the conductive layer 112b, but not limited herein. The circuit structure 100 may be a redistribution layer (RDL), so as to redistribute the circuit. For example, the contact positions of the circuit may be changed or the fan-out area of the circuit may be increased through one or more metal wiring processes, but not limited herein. In the present disclosure, the direction Y may be a normal direction of the electronic device ED, which is opposite to a top-view direction of the electronic device ED, while a direction X may be parallel to a horizontal direction, which is parallel to a surface (such as the upper surface or lower surface) of the electronic unit 300, and the direction Y may be perpendicular to the direction X, but not limited herein.

In some embodiments, the conductive layer 112a, the insulating layer 114a, the conductive layer 112b and the insulating layer 114b that are patterned may be alternately formed in sequence in the direction Y, and then the conductive pad 110 is formed on the insulating layer 114b or in a recess 114G of the insulating layer 114b, so as to form the circuit structure 100. One or plural connection holes may be included in the insulating layer 114, and the conductive layer 112a, the conductive layer 112b and the conductive pad 110 may be electrically connected through the connection holes, but not limited herein. The conductive pad 110 may be, for example, but not limited to, an under-bump metallization (UBM). The conductive pad 110 may include copper, nickel, gold, silver, titanium, other suitable conductive materials or combinations of the above materials, such as a material that can be mechanically deformed at the temperature and pressure while the conductive pad 110 is being bonded (e.g., at 200-400° C. and 1-100 MPa), but not limited herein. The conductive pad 110 and the conductive layer 112 may respectively be a single-layer structure or a multi-layer stacked structure. The material of the conductive pad 110 may be the same as or different from the material of the conductive layer 112. The conductive layer 112 may include metal materials such as titanium, copper, aluminum, tin, nickel, gold or silver or other suitable conductive materials. The insulating layer 114 may include organic materials or inorganic materials. The organic materials include, for example, polyimide (PI), photosensitive polyimide (PSPI), epoxy, Ajinomoto build-up film (ABF) or other suitable materials, but not limited herein. The inorganic materials include, for example, silicon oxide (SiOx), silicon nitride (SiNx) or other suitable materials, but not limited herein. The circuit structure 100 may further include active elements and/or passive elements, such as diodes, transistors, capacitors, resistors, inductors, antenna elements, which may be electrically connected to wires formed by the conductive layer 112. The transistor includes, for example, a thin film transistor (TFT), and the thin film transistor may include a gate, a source, a drain and a semiconductor layer, but not limited herein.

At least a portion of the bonding element 200 is disposed in the accommodating recess 120 of the conductive pad 110, and the electronic unit 300 is electrically connected to the conductive pad 110 through the bonding element 200, so that the electronic unit 300 is electrically connected to the circuit structure 100. Specifically, the electronic device ED may include one or plural bonding elements 200, and at least a portion of one of the bonding elements 200 may be correspondingly disposed in the accommodating recess 120 of the conductive pad 110 and connected to the conductive pad 110, so that the electronic unit 300 may be electrically connected to the conductive pad 110 through the bonding element 200. The bonding element 200 may be, for example, a pillar, a bump, a solder ball or a pad. The bonding element 200 may include, copper, tin, nickel, gold, lead, aluminum, other suitable conductive materials or combinations of the above materials, but not limited herein. The electronic unit 300 may be, for example, a printed circuit board (PCB), a die, a chip, an integrated circuit (IC), a diode, a capacitor, a resistor or other suitable active elements or passive elements, but not limited herein.

According to the embodiments of the present disclosure, the accommodating recess 120 of the conductive pad 110 has a bottom surface 122 and an opening 124 opposite to the bottom surface 122, and a width W1 of the bottom surface 122 is greater than a width W2 of the opening 124. The term “a width of the bottom surface of the accommodating recess” referred in the present disclosure may mean the width measured from an end of the bottom surface of the accommodating recess to another end thereof in the direction X, and the term “a width of the opening of the accommodating recess” referred in the present disclosure may mean the minimum width measured from an end of the opening of the accommodating recess to another end thereof in the direction X. For example, as shown in FIG. 2, the accommodating recess 120 is a recess formed on an upper surface 110a of the conductive pad 110. The accommodating recess 120 may have the bottom surface 122, the opening 124 and a side wall 126, the opening 124 is opposite to the bottom surface 122, and the side wall 126 is connected to the bottom surface 122. The width W1 may be measured from an end of the bottom surface 122 of the accommodating recess 120 to another end thereof in the direction X, and the minimum width W2 may be measured from an end of the opening 124 of the accommodating recess 120 to another end thereof in the direction X. Furthermore, the width W1 of the bottom surface 122 is greater than the width W2 of the opening 124 (i.e., W1>W2). By disposing at least a portion of the bonding element 200 in the accommodating recess 120 with the lower width W1 greater than the upper width W2, the accuracy of alignment between the bonding element 200 and the conductive pad 110 may be improved, so as to mitigate the displacement of the bonding element 200, thereby improving the reliability of the electronic device ED.

In the embodiment shown in FIG. 2, a depth T1 of the accommodating recess 120 may be less than a thickness T2 of the conductive pad 110 (i.e., T1<T2). In some embodiments, the depth T1 of the accommodating recess 120 may be less than or equal to two-thirds of the thickness T2 of the conductive pad 110, so that the accommodating recess 120 may receive and accommodate at least a portion of the bonding element 200, thereby improving the accuracy of alignment, but not limited herein. For example, the depth T1 of the accommodating recess 120 may be measured from the opening 124 to the bottom surface 122 in the direction Y, and the thickness T2 of the conductive pad 110 may be measured from the upper surface 110a of the conductive pad 110 to a lower surface 110b thereof opposite to the upper surface 110a in the direction Y, but not limited herein.

In some embodiments, in a cross-sectional view of a portion of the electronic device ED shown in FIG. 2, the shortest distance between an edge 110e of the conductive pad 110 and the bottom surface 122 of the accommodating recess 120 is defined as a first distance H1, the shortest distance between the edge 110e of the conductive pad 110 and the opening 124 of the accommodating recess 120 is defined as a second distance H2, and the first distance H1 is less than the second distance H2 (i.e., H1<H2). That is to say, in the direction X, the first distance H1 exists between the edge 110e of the conductive pad 110 and an end of the bottom surface 122 adjacent to the edge 110e, and the second distance H2 exists between the edge 110e of the conductive pad 110 and an end of the opening 124 adjacent to the edge 110e, wherein the first distance H1 is less than the second distance H2.

In some embodiments, as shown in FIG. 2, an included angle θ exists between the side wall 126 and the bottom surface 122 of the accommodating recess 120, and the included angle θ may be less than 90 degrees. According to the embodiments, the included angle θ is defined by an extension line of the side wall 126 and an extension line of the bottom surface 122 of the accommodating recess 120. In some embodiments, a width of the accommodating recess 120 may gradually decrease from the bottom surface 122 to the opening 124, that is, the side wall 126 may be an inclined wall and the width W1 of the bottom surface 122 is the maximum width of the accommodating recess 120 while the width W2 of the opening 124 is the minimum width of the accommodating recess 120, so that the shape of the accommodating recess 120 in the cross-sectional view may be a trapezoid, that is, the area of the bottom surface 122 of the accommodating recess 120 is greater than the area of the opening 124 of the accommodating recess 120, but not limited herein.

According to the structural design of the conductive pad 110 shown in FIG. 2, the conductive pad 110 may contact the bonding element 200, so that the bonding element 200 may be embedded in the accommodating recess 120 of the conductive pad 110. That is to say, the upper portion of the accommodating recess 120 of the conductive pad 110 (e.g., the edge of the opening 124) may contact the bonding element 200 to fix the bonding element 200, thereby improving the accuracy of alignment between the bonding element 200 and the conductive pad 110. In addition, since the conductive pad 110 can contact the bonding element 200, the whole conductive pad 110 is not required to have a large size and a relative small size of the whole conductive pad 110 is sufficient for connecting with the bonding element 200, that is, the size of the whole conductive pad 110 can be reduced. For example, a width W3 of the whole conductive pad 110 may be small, thereby reducing the space occupied by the conductive pad 110 in the structure, so that the design of the fan-out circuit may be more flexible. On the other hand, since the size of the conductive pad 110 is reduced, the material cost may be saved.

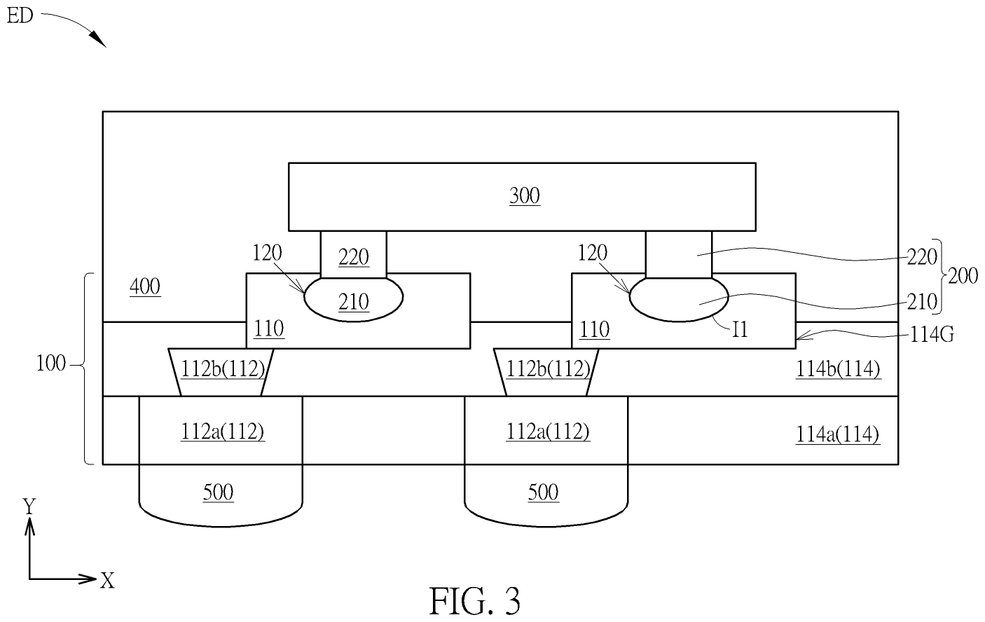

In some embodiments, as shown in FIG. 1 and FIG. 2, the bonding element 200 may include a bonding portion 210 and a conductive pillar 220. The conductive pillar 220 is located between the electronic unit 300 and the bonding portion 210, and the depth T1 of the accommodating recess 120 may be greater than or equal to a thickness T3 of the bonding portion 210. For example, the thickness T3 of the bonding portion 210 may be measured in the direction Y from the upper surface of the bonding portion 210 (e.g., an interface I between the bonding portion 210 and the conductive pillar 220) to an end of the bonding portion 210 closest to the bottom surface 122 of the accommodating recess 120. The bonding portion 210 may include solder, such as tin, gallium, nickel, gold, copper, aluminum, silver, other material that can be melted at the temperature for bonding the bonding element 200 (e.g., at 200-400° C.) or combinations of the above materials, so that at least a portion of the accommodating recess 120 may be filled with the bonding portion 210. That is to say, a portion of the accommodating recess 120 may be filled by the bonding portion 210 (as shown in FIG. 1), or the whole accommodating recess 120 may be filled by the bonding portion 210 (as shown in FIG. 3). Since the bonding portion 210 is disposed in the accommodating recess 120, the size of the bonding portion 210 does not need to be too large and it is still sufficient to allow the bonding element 200 to be fully bonded to the conductive pad 110. That is to say, the size of the bonding portion 210 may be reduced, and therefore the material cost may be saved.

The conductive pillar 220 may include copper, nickel, gold, silver, other suitable conductive materials or combinations of the above materials, such as a material that is not melted at the temperature while the bonding element 200 is bonded, but not limited herein. The interface I between the bonding portion 210 and the conductive pillar 220 may be lower than the upper surface 110a of the accommodating recess 120 when the depth T1 of the accommodating recess 120 is greater than the thickness T3 of the bonding portion 210, so that the bonding portion 210 is disposed in the accommodating recess 120, and the conductive pad 110 may contact a portion of the conductive pillar 220. That is to say, the upper portion of the accommodating recess 120 (e.g., the edge of the opening 124) contacts the conductive pillar 220, so as to fix the bonding element 200.

Please refer to FIG. 3, which is a cross-sectional schematic diagram of an electronic device according to another embodiment of the present disclosure. As shown in FIG. 3, in some embodiments, at least more than 90% of the space of the accommodating recess 120 may be filled with the bonding portion 210 of the bonding element 200. For example, after the reaction of the process (such as, but not limited to, a wetting process), the accommodating recess 120 may be completely filled with the bonding portion 210 of the bonding element 200, so that there is no gap between the bonding element 200 and the accommodating recess 120, but not limited herein. In the cross-sectional view shown in FIG. 3, the boundary between the accommodating recess 120 of the conductive pad 110 and the bonding portion 210 of the bonding element 200 (such as an interface I1 between the accommodating recess 120 and the bonding portion 210) may be an arc-shape, but not limited herein. In some embodiments, the bonding portion 210 of the bonding element 200 and the conductive pad 110 may further form an intermetallic compound (IMC) structure, for example, but not limited herein. According to the embodiment shown in FIG. 3, by disposing a portion of the bonding element 200 (such as the bonding portion 210) in the accommodating recess 120, the contact area between the bonding element 200 and the conductive pad 110 may be increased, so as to reduce the risk of poor contact due to insufficient contact area therebetween after the reaction, or the material cost thereof may be saved, but not limited herein.

According to the structure of the conductive pad 110 and the structure of the bonding element 200 including the bonding portion 210 and the conductive pillar 220 described above, in the manufacturing process for the electronic device ED of some embodiments, when electrically connecting the electronic unit 300 to the conductive pad 110 through the bonding element 200, that is, when bonding the bonding element 200 to the conductive pad 110, heating and pressurizing may be applied to the structure at the same time, so that the solder of the bonding portion 210 is melted from the solid state to the liquid state at the process temperature (e.g., 200-400° C.), and the conductive pad 110 is deformed at the process pressure (e.g., 1-100 MPa) to contact or clamp the conductive pillar 220. The bonding portion 210 is in the liquid state during pressurizing, which may provide a buffer function to relieve stress. In the manufacturing process for the electronic device ED of other embodiments, when bonding the bonding element 200 to the conductive pad 110, at first the structure may be applied with simply pressure, without heating. Since the whole bonding element 200 is in the solid state at this time, greater pressure may be applied to the conductive pad 110 to cause greater deformation of the conductive pad 110. Therefore, the conductive pad 110 may provide greater clamping force to contact or clamp the conductive pillar 220 provided that the process is under control such that the structure can be free from damage. Then, heating process to the structure is carried out, so that the solder of the bonding portion 210 is melted at the process temperature to fill the accommodating recess 120. However, the manufacturing process of the electronic device ED according to the embodiment of the present disclosure is not limited to the above.

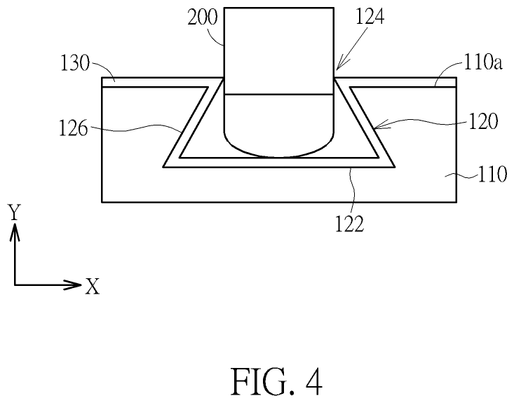

Please refer to FIG. 4, which is a partial cross-sectional schematic diagram of a variation embodiment of a conductive pad and a bonding element according to the present disclosure. As shown in FIG. 4, in some embodiments, the electronic device ED may further include an intermediate layer 130, and at least a portion of the intermediate layer 130 is disposed in the accommodating recess 120 and connected to the bonding element 200. For example, the intermediate layer 130 may cover the bottom surface 122 and/or the side wall 126 of the accommodating recess 120, or the intermediate layer 130 may further cover a portion of the upper surface 110a of the conductive pad 110. The intermediate layer 130 may be, for example, solder or conductive adhesive. The solder may include tin, gallium, silver, other material that can be melted at the temperature for boding the bonding element 200, or combinations of the above materials, but not limited herein. The conductive adhesive may include an anisotropic conductive film (ACF), but not limited herein. Therefore, the conductive pad 110 may be bonded to the bonding element 200 through the intermediate layer 130, so as to further improve the bonding strength between the conductive pad 110 and the bonding element 200.

The manufacturing process of the electronic device ED in the present disclosure may be, for example, a panel-level package (FOPLP) process, and may be a RDL-first process or a chip-first process, but not limited herein. Please refer to FIG. 1, the electronic device ED shown in FIG. 1 may be manufactured by a RDL-first process, wherein the circuit structure 100 including the redistribution layer is formed first, and then the electronic unit 300 may be disposed on the circuit structure 100 by flip-chip bonding, for example, but not limited herein. According to the embodiment shown in FIG. 1, the electronic device ED may further include a protective layer 400, and the protective layer 400 may surround the electronic unit 300 and the bonding element 200, so as to isolate moisture and air and/or reduce damage to the electronic unit 300 and the bonding element 200. The term “surround” referred in the present disclosure may mean that in a cross-sectional view of the electronic device ED, an element or layer may contact at least a side surface of the corresponding element or layer that is surrounded. For example, the protective layer 400 may contact at least the side surface of the electronic unit 300 and the side surface of the bonding element 200. As shown in FIG. 1, the protective layer 400 may cover the side surface and the upper surface of the electronic unit 300 and cover and contact a portion of the surface of the circuit structure 100, but not limited herein. In other embodiments, the upper surface of the electronic unit 300 is not covered by the protective layer 400. For example, the protective layer 400 may expose the upper surface of the electronic unit 300 by a grinding process. The protective layer 400 may include, for example, epoxy, ceramic, epoxy molding compound (EMC), other suitable materials or combinations of the above materials, but not limited herein.

In some embodiments, as shown in FIG. 1, the electronic device ED may further include another bonding element 500. The bonding element 500 and the bonding element 200 are respectively disposed on opposite two sides of the circuit structure 100, that is, the bonding element 500 may be disposed on a side of the circuit structure 100 opposite to the electronic unit 300, and the bonding element 500 is electrically connected to the circuit structure 100. The bonding element 500 may be, for example, an under-bump metallization (UBM), a bump, a solder ball or a pad. The bonding element 500 may include copper, tin, nickel, gold, lead, other suitable conductive materials or combinations of the above materials, but not limited herein. In some embodiments, the electronic device ED may further include another electronic unit (not shown in FIG. 1). The another electronic unit and the electronic unit 300 may be respectively disposed on opposite two sides of the circuit structure 100, and the another electronic unit may be electrically connected to the circuit structure 100 through the bonding element 500, but not limited herein.

Some embodiments of the electronic devices and the manufacturing processes for the electronic devices of the present disclosure will be detailed in the following. In order to simplify the illustration, the same elements in the following would be labeled with the same symbols. The differences between different embodiments are described in detail below, and the same features would not be described redundantly. Each of the embodiments and another embodiment of the present disclosure may be combined and adjusted with each other.

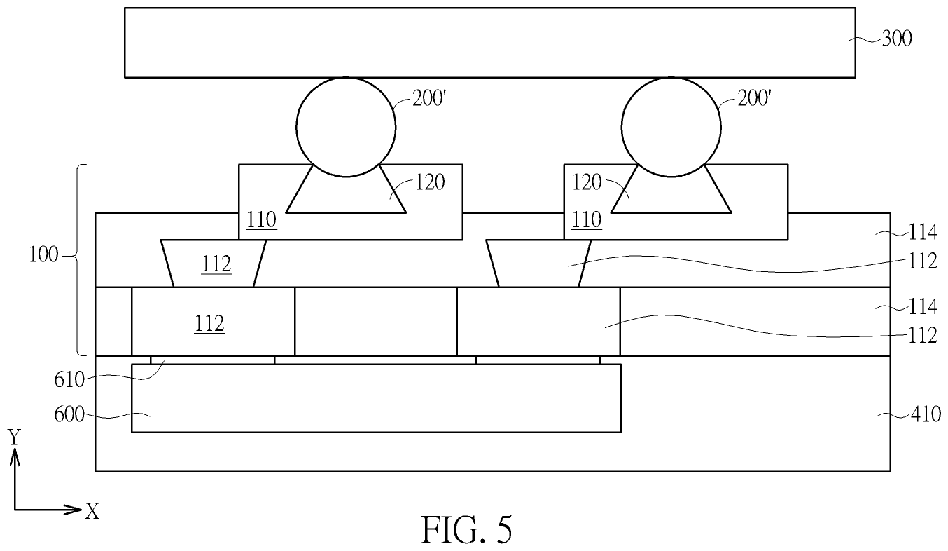

Please refer to FIG. 5, which is a cross-sectional schematic diagram of an electronic device according to still another embodiment of the present disclosure, wherein the electronic device ED shown in FIG. 5 may be manufactured by a chip-first process, but not limited herein. According to the embodiment shown in FIG. 5, the type of the bonding element 200′ may be different from the type of the bonding element 200 of the embodiment shown in FIG. 1. At least a portion of the bonding element 200′ may be disposed in the accommodating recess 120 of the conductive pad 110, and the electronic unit 300 may be electrically connected to the conductive pad 110 through the bonding element 200′, thereby electrically connecting the electronic unit 300 to the circuit structure 100. However, the type of the bonding element 200′ may be the same as the type of the bonding element 200 of the embodiment shown in FIG. 1 in other embodiments, which is not limited thereto. In some embodiments, as shown in FIG. 5, the electronic device ED may further include another electronic unit 600. The electronic unit 600 and the electronic unit 300 are respectively disposed on opposite two sides of the circuit structure 100, and the electronic unit 600 may be electrically connected to the circuit structure 100. The electronic unit 600 may be, for example, a printed circuit board (PCB), a die, a chip, an integrated circuit (IC), a diode, a capacitor, a resistor or other suitable active elements or passive elements, but not limited herein. The electronic unit 600 may further include, for example, a bonding pad 610, and the conductive layer 112 in the circuit structure 100 may be electrically connected to the bonding pad 610 of the electronic unit 600. The bonding pad 610 may include aluminum, copper, tin, nickel, gold, lead, other suitable conductive materials or combinations of the above materials, but not limited herein. In addition, as shown in FIG. 5, the electronic device ED may further include a protective layer 410, and the protective layer 410 surrounds the electronic unit 600. For example, the protective layer 410 may cover and contact the side surface and the lower surface of the electronic unit 600 and cover and contact a portion of the surface of the circuit structure 100, but not limited herein. In other embodiments, the lower surface of the electronic unit 600 is not covered by the protective layer 410. For example, the protective layer 410 may expose the lower surface of the electronic unit 600 by a grinding process. The protective layer 410 may include, for example, epoxy, ceramic, epoxy molding compound (EMC), other suitable materials or combinations of the above materials, but not limited herein.

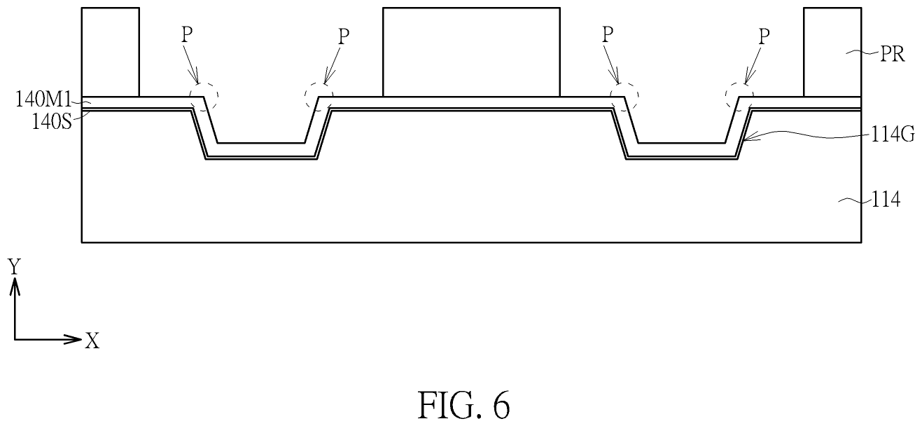

Please refer to FIG. 6 to FIG. 8. FIG. 6 to FIG. 8 are schematic diagrams illustrating a part of the process of a conductive pad according to another embodiment of an electronic device of the present disclosure. In order to simplify the illustration, the conductive layers in the circuit structure 100 are omitted in FIG. 6 to FIG. 8, and the entirety of multiple insulating layers in the circuit structure 100 is represented by an insulating layer 114. The configuration of multiple insulating layers 114 and multiple conductive layers 112 in the circuit structure 100 may be referred to, for example, FIG. 1, but not limited thereto. As shown in FIG. 6 to FIG. 8, the manufacturing process of a conductive pad 140 according to another embodiment of the present disclosure may include the following steps, for example. First, as shown in FIG. 6, the uppermost insulating layer 114 may be patterned to form one or plural recesses 114G, then a seed layer 140S is formed on the insulating layer 114, and then a metal layer 140M1 is formed on the seed layer 140S. For example, but not limited to, the metal layer 140M1 may be formed by an electroplating process, wherein the seed layer 140S may contribute to the formation of the metal layer 140M1 or improve adhesion. Then, a photoresist PR that is patterned may be formed on the metal layer 140M1. The patterned photoresist PR may be formed on a portion of the metal layer 140M1 that does not correspond to the region where the recesses 114G are located. For example, the recess 114G may be located between adjacent photoresist patterns.

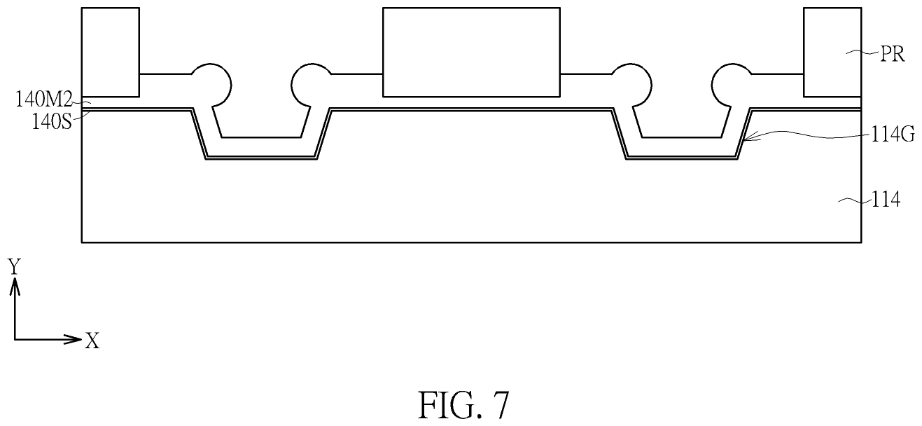

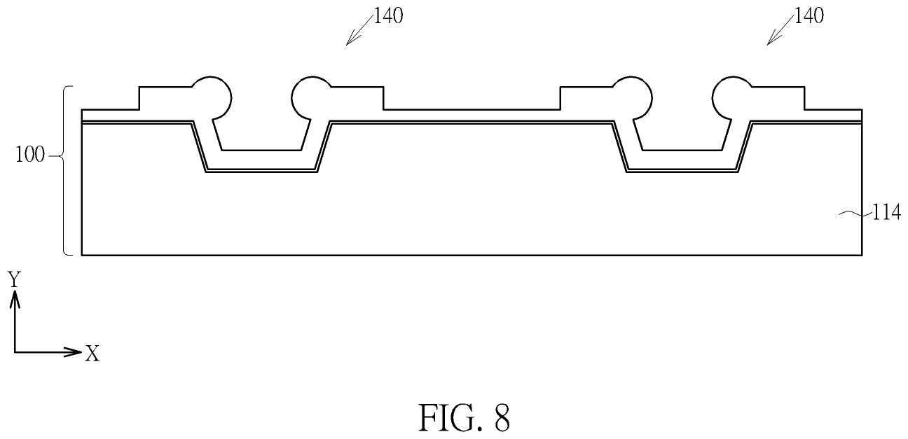

Then, the electroplating process may be performed to continue to grow metal material on the metal layer 140M1 shown in FIG. 6, so as to form a metal layer 140M2 shown in FIG. 7. Specifically, for example, by adjusting and controlling the additive agent in the electroplating solution, the additive agent is more easily adsorbed on end portions P shown by the dotted frame in FIG. 6 and may increase the growth rate of the metal at the end portions P, thereby forming the metal layer 140M2 shown in FIG. 7. Then, as shown in FIG. 8, the photoresist PR may be removed to obtain a circuit structure 100 including one or plural conductive pads 140. According to the embodiment shown in FIG. 6 to FIG. 8, the material of the seed layer 140S may include, for example, titanium, copper, molybdenum, aluminum, nickel, silver, tin, other suitable conductive materials or combinations of the above materials, but not limited herein. The material of the metal layer 140M1 and/or the metal layer 140M2 may include copper, nickel, gold, silver, other suitable conductive materials or combinations of the above materials, such as a material that can be mechanically deformed at the temperature and pressure while bonding the formed conductive pad 140 (e.g., at 200-400° C. and 1-100 MPa), but not limited herein.

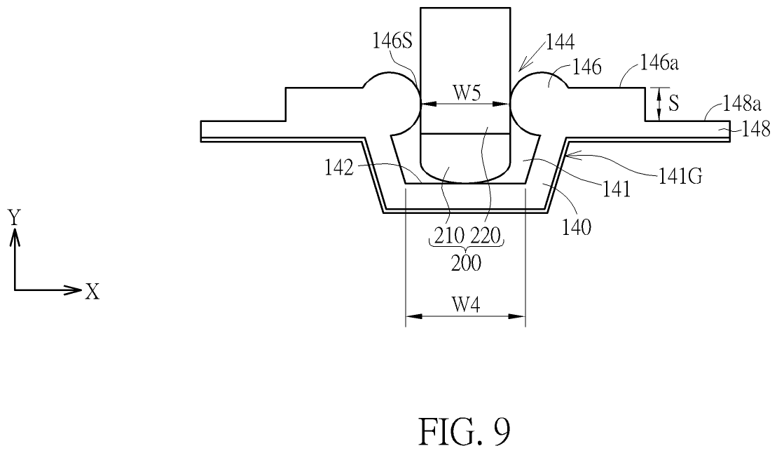

Please refer to FIG. 9, which is a partial cross-sectional schematic diagram illustrating the connection portion of a conductive pad shown in FIG. 8 and a bonding element. As shown in FIG. 9, the conductive pad 140 may have an accommodating recess 141. The accommodating recess 141 has a bottom surface 142 and an opening 144 opposite to the bottom surface 142, and a width W4 of the bottom surface 142 is greater than a width W5 of the opening 144 (i.e., W4>W5). The width W4 may be measured from an end of the bottom surface 142 of the accommodating recess 141 to another end thereof in the direction X, and the minimum width W5 may be measured from an end of the opening 144 of the accommodating recess 141 to another end thereof in the direction X. Specifically, the conductive pad 140 may include a protruding portion 146, and the protruding portion 146 surrounds the opening 144, wherein the minimum distance between the opposite parts of the protrusion 146 may be the width W5 of the opening 144. In some embodiments, the protruding portion 146 of the conductive pad 140 may contact the bonding element 200, so that the bonding element 200 may be embedded in the accommodating recess 141 of the conductive pad 140. That is to say, the protruding portion 146 may contact the bonding element 200 to fix the bonding element 200. For example, the bonding portion 210 of the bonding element 200 may be disposed in the accommodating recess 141, and the protruding portion 146 may contact a portion of the conductive pillar 220 of the bonding element 200, but not limited herein. The detailed structure and materials of the bonding portion 210 and the conductive pillar 220 of the bonding element 200 may be, for example, referred to the previous embodiments, which will not be redundantly described herein. A side of the protruding portion 146 contacting the bonding element 200 may have an arc surface 146S. For example, the arc surface 146S may be formed by adsorbing the additive agent on the end portions P and increasing the growth rate of metal at the end portions P, as shown in FIG. 6 and FIG. 7, but not limited herein. According to the embodiments shown in FIG. 9, the conductive pad 140 may further include an extending portion 148. The extending portion 148 extends from the protruding portion 146 toward a direction opposite to the opening 144, and a step difference S exists between an upper surface 148a of the extending portion 148 and an upper surface 146a of the protruding portion 146. That is to say, in the direction Y, the shortest distance between the upper surface 148a of the extending portion 148 and the upper surface 146a of the protruding portion 146 is defined as the step difference S, wherein the upper surface 148a of the extending portion 148 may be substantially parallel to the direction X, but not limited herein.

From the above description, according to the electronic devices of the embodiments of the present disclosure, by disposing the conductive pad having the accommodating recess with a lower width greater than the upper width and arranging at least a portion of the bonding element in the accommodating recess, the accuracy of alignment between the bonding element and the conductive pad may be improved, thereby improving the reliability of the electronic device. In addition, the conductive pad may be effectively electrically connected to the bonding element by contacting the bonding element with the conductive pad, so the bonding element and the conductive pad in the electronic device of the present disclosure may have a smaller size in comparison with the prior art, thereby making the design of the fan-out circuit more flexible and/or saving the cost.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a circuit structure comprising a conductive pad, wherein the conductive pad has an accommodating recess;
a bonding element, wherein at least a portion of the bonding element is disposed in the accommodating recess; and
an electronic unit electrically connected to the conductive pad through the bonding element,
wherein the accommodating recess has a bottom surface and an opening opposite to the bottom surface, and a width of the bottom surface is greater than a width of the opening.

2. The electronic device according to claim 1, wherein a depth of the accommodating recess is less than a thickness of the conductive pad.

3. The electronic device according to claim 1, wherein in a cross-sectional view of the electronic device, a shortest distance between an edge of the conductive pad and the bottom surface is defined as a first distance, a shortest distance between the edge of the conductive pad and the opening is defined as a second distance, and the first distance is less than the second distance.

4. The electronic device according to claim 1, wherein the accommodating recess has a side wall connected to the bottom surface, and an included angle between the side wall and the bottom surface is less than 90 degrees.

5. The electronic device according to claim 1, wherein the bonding element comprises a bonding portion and a conductive pillar, and the conductive pillar is located between the electronic unit and the bonding portion, wherein a depth of the accommodating recess is greater than or equal to a thickness of the bonding portion.

6. The electronic device according to claim 5, wherein the bonding portion is disposed in the accommodating recess, and the conductive pad contacts a portion of the conductive pillar.

7. The electronic device according to claim 5, wherein the bonding portion comprises solder, and at least a portion of the accommodating recess is filled with the bonding portion.

8. The electronic device according to claim 1, wherein the conductive pad contacts the bonding element.

9. The electronic device according to claim 1, further comprising an intermediate layer, wherein at least a portion of the intermediate layer is disposed in the accommodating recess and connected to the bonding element.

10. The electronic device according to claim 1, wherein a width of the accommodating recess gradually decreases from the bottom surface to the opening.

11. The electronic device according to claim 1, wherein the conductive pad comprises a protruding portion surrounding the opening.

12. The electronic device according to claim 11, wherein the protruding portion contacts the bonding element.

13. The electronic device according to claim 12, wherein a side of the protruding portion contacting the bonding element has an arc surface.

14. The electronic device according to claim 12, wherein the conductive pad further comprises an extending portion extending from the protruding portion toward a direction opposite to the opening, wherein a step difference exists between an upper surface of the extending portion and an upper surface of the protruding portion.

15. The electronic device according to claim 1, further comprising a protective layer surrounding the electronic unit and the bonding element.

16. The electronic device according to claim 1, further comprising another bonding element, wherein the another bonding element and the bonding element are respectively disposed on opposite two sides of the circuit structure, and the another bonding element is electrically connected to the circuit structure.

17. The electronic device according to claim 1, further comprising another electronic unit, wherein the another electronic unit and the electronic unit are respectively disposed on opposite two sides of the circuit structure, and the another electronic unit is electrically connected to the circuit structure.

18. The electronic device according to claim 17, further comprising a protective layer surrounding the another electronic unit.

19. The electronic device according to claim 1, wherein the circuit structure further comprises an insulating layer, and the conductive pad is disposed on the insulating layer.

20. The electronic device according to claim 19, wherein the circuit structure is a redistribution layer.
